(19) United States
(12) Patent Application Publication
(10) Pub. No.: US 2013/0026503 A1
(43) Pub. Date: Jan. 31, 2013

(54) LIGHT EMITTING DIODE DISPLAY AND MANUFACTURING METHOD THEREOF

(71) Applicants: Jung-Hyun Son, Yongin-city (KR); Hoon Kim, Yongin-city (KR); Byung-Hee Kim, Yongin-city (KR)

(72) Inventors: Jung-Hyun Son, Yongin-city (KR); Hoon Kim, Yongin-city (KR); Byung-Hee Kim, Yongin-city (KR)

(21) Appl. No.: 13/474,659

(22) Filed: May 17, 2012

(30) Foreign Application Priority Data
Jul. 29, 2011 (KR) 10-2011-0076041

(51) Int. Cl. H01L 33/62

(52) U.S. Cl. 257/88; 438/34; 257/E33.066

(57) ABSTRACT

An organic light emitting diode (OLED) display includes a substrate, an OLED on the substrate, and an encapsulation layer on the substrate with the OLED therebetween. The encapsulation layer includes a plurality of metal layers. Two of the plurality of metal layers are directly attached to each other.

### CROSS-REFERENCE TO RELATED APPLICATION

This application claims priority to and the benefit of Korean Patent Application No. 10-2011-0076041, filed in the Korean Intellectual Property Office on Jul. 29, 2011, the entire content of which is incorporated herein by reference.

### BACKGROUND

1. Field

Aspects of embodiments of the present invention relate generally to an organic light emitting diode (OLED) display and a method for manufacturing the OLED display.

2. Description of Related Art

Display devices display images. Recently, an organic light emitting diode (OLED) display has been in the spotlight.

Unlike a liquid crystal display, the OLED display has a self-emitting characteristic and does not need a separate light source. Accordingly, the thickness and weight of the OLED display are decreased compared to those of the liquid crystal display. In addition, the OLED display has high-grade characteristics such as low power consumption, high luminance, high reaction speed, and the like.

The OLED display may include a substrate, an OLED on the substrate, an encapsulation layer for encapsulating the OLED, and a sealant for adhering the encapsulation layer to the substrate. The OLED display may include an encapsulation layer having a metal layer.

However, when a pinhole is formed in the metal layer in such an OLED display, external moisture may penetrate into the OLED. This may create a problem in the OLED.

The above information disclosed in this Background section is only for enhancement of understanding of the background of the present invention. As such, it may contain information that does not form the prior art that is already known in this country to a person of ordinary skill in the art.

### SUMMARY

Aspects of embodiments of the present invention relate to an organic light emitting diode (OLED) display for encapsulating an OLED by using a metal layer, and a method for manufacturing the OLED display. Further aspects of embodiments of the present invention provide an OLED display for providing improved sealing performance of an OLED, and a method for manufacturing the OLED display.

According to an exemplary embodiment of the present invention, an organic light emitting diode (OLED) display is provided. The OLED display includes a substrate, an OLED on the substrate, and an encapsulation layer on the substrate with the OLED therebetween. The encapsulation layer includes a plurality of metal layers. Two of the plurality of metal layers are directly attached to each other.

Micropores may be provided at an interface where the two of the plurality of metal layers contact.

All of the plurality of metal layers may include a same metal.

Different ones of the plurality of metal layers may include different metals.

Each of the plurality of metal layers may include at least one of aluminum (Al), copper (Cu), or stainless steel.

The OLED display may further include a resin layer on the plurality of metal layers. The resin layer may be configured to reinforce strength of the plurality of metal layers.

The resin layer may be attached to an uppermost layer of the plurality of metal layers.

The resin layer may include at least one of glass fiber reinforced plastic (FRP), polyethylene terephthalate (PET), or polymethyl methacrylate (PMMA).

The OLED display may further include an adhesive layer between the substrate and the encapsulation layer and on the OLED. The adhesive layer may be configured to adhere and seal the encapsulation layer to the substrate.

According to another exemplary embodiment of the present invention, a method for manufacturing an organic light emitting diode (OLED) display is provided. The method includes: forming an OLED on a substrate; forming an encapsulation layer by directly attaching two of a plurality of metal layers to each other; and adhering and sealing the encapsulation layer to the substrate with the OLED therebetween.

The two of the plurality of metal layers may respectively include a first metal layer and a second metal layer. The directly attaching of the two of the plurality of metal layers may include: forming protrusions and depressions on a surface of the first metal layer; stacking the second metal layer on the surface of the first metal layer; rolling the first metal layer and the second metal layer; and heat treating the first metal layer and the second metal layer.

The method may further include attaching a resin layer for reinforcing strength of the plurality of metal layers on an uppermost layer of the plurality of metal layers.

According to embodiments of the present invention, an OLED display with improved sealing performance of an OLED, and a method for manufacturing the OLED display, are provided.

### BRIEF DESCRIPTION OF THE DRAWINGS

FIG. 1 shows a cross-sectional view of an organic light emitting diode (OLED) display according to a first exemplary embodiment of the present invention.

FIG. 2 shows a layout view of a configuration of a pixel of the OLED display of FIG. 1.

FIG. 3 shows a cross-sectional view with respect to a line III-III of FIG. 2.

FIG. 4, which includes FIG. 4(A) and FIG. 4(B), are enlarged photographs of part A in FIG. 3.

FIG. 5 shows a flowchart of a method for manufacturing an OLED display according to a second exemplary embodiment of the present invention.

FIG. 6 and FIG. 7 show the method of FIG. 5.

FIG. 8 shows a cross-sectional view of an OLED display according to a third exemplary embodiment of the present invention.

FIG. 9, which includes FIG. 9(A) and FIG. 9(B), are enlarged photographs of part B of FIG. 8.

### DETAILED DESCRIPTION

The present invention will be described more fully hereinafter with reference to the accompanying drawings, in which exemplary embodiments of the present invention are shown. As those skilled in the art would realize, the described embodiments may be modified in various different ways, all without departing from the spirit or scope of the present invention.

Accordingly, the drawings and description are to be regarded as illustrative in nature and not restrictive, and like reference numerals designate like elements throughout the specification. In addition, the size and thickness of each component shown in the drawings are arbitrarily shown for ease of understanding and description, but the present invention is not limited thereto.

In the drawings, the thickness of layers, films, panels, regions, etc., may be exaggerated for clarity. In the drawings, for ease of understanding and description, the thicknesses of some layers and areas may be exaggerated. It will be understood that when an element such as a layer, film, region, or substrate is referred to as being “on” another element, it can be directly on the other element or intervening elements may also be present.

In addition, unless explicitly described to the contrary, the word “comprise” and variations such as “comprises” or “comprising” will be understood to imply the inclusion of stated elements but not the exclusion of any other elements. Further, throughout the specification, “on” implies being positioned above or below a target element and does not imply being necessarily positioned on the top based on a gravity direction.

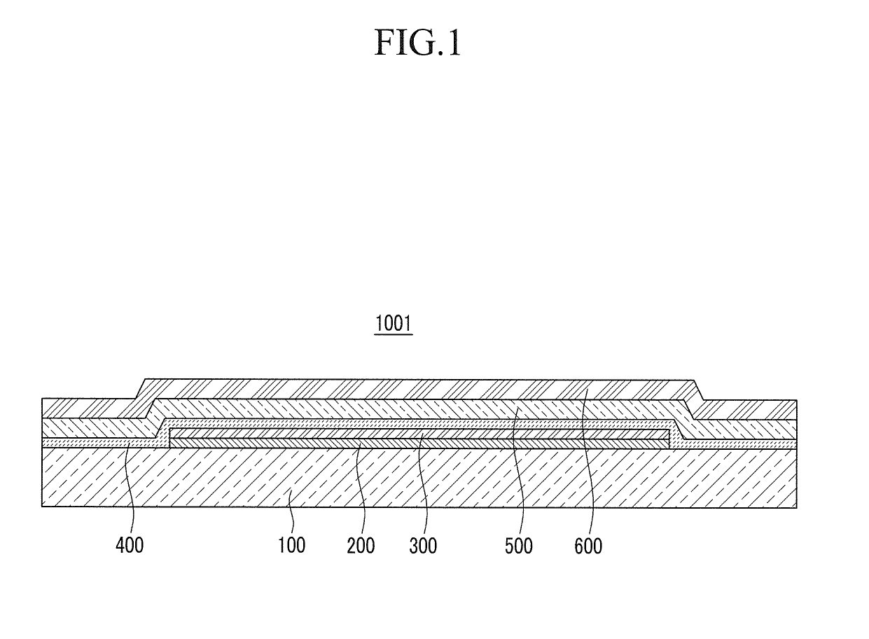

Referring to FIG. 1 to FIG. 4, an organic light emitting diode (OLED) display 1001 according to a first exemplary embodiment of the present invention will now be described.

FIG. 1 shows a cross-sectional view of the OLED display 1001.

As shown in FIG. 1, the OLED display 1001 includes a substrate 100, wiring 200, an OLED 300, an adhesive layer 400, an encapsulation layer 500, and a resin layer 600.

The substrate 100 may include polymer, quartz, glass, or metal, and is made of a light transmissive material. The wiring 200 and the OLED 300 are located on the substrate 100. The substrate 100 faces the encapsulation layer 500 with the wiring 200 and the OLED 300 therebetween. The encapsulation layer 500 is adhered to the substrate and sealed by the adhesive layer 400 with the wiring 200 and the OLED 300 sealed therebetween. The substrate 100 and the encapsulation layer 500 protect the wiring 200 and the OLED 300 from external interference and moisture.

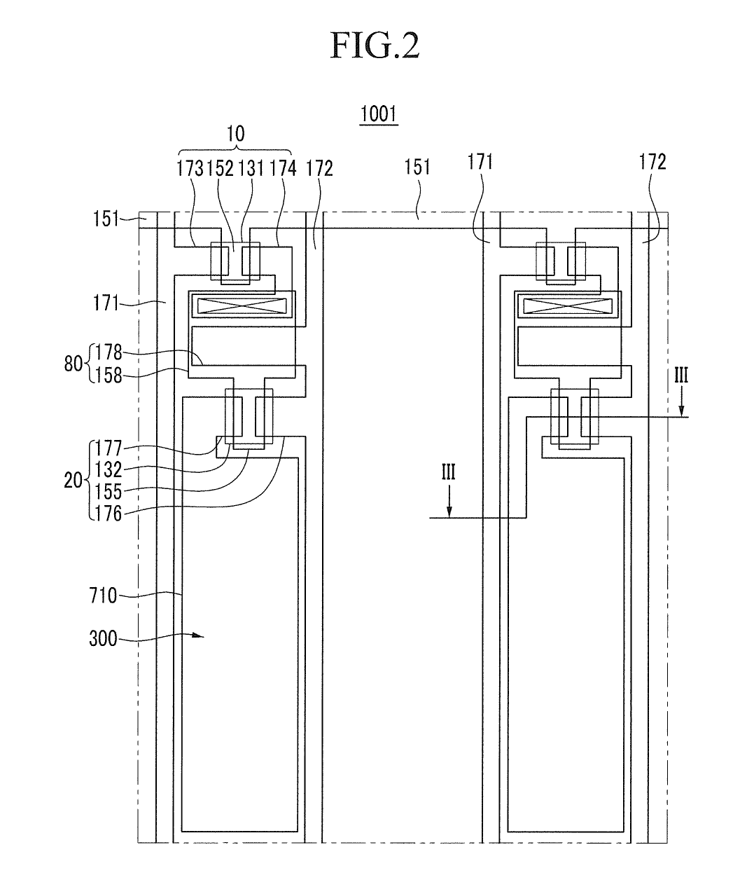

The wiring 200 includes switching and driving thin film transistors 10 and 20 as shown in FIG. 2, and drives the OLED 300 by transmitting a signal to the OLED 300. The OLED 300 emits light according to the signal transmitted by the wiring 200. The OLED 300 is located on the wiring 200 and the substrate 100, receives the signal from the wiring 200, and displays an image according to the signal.

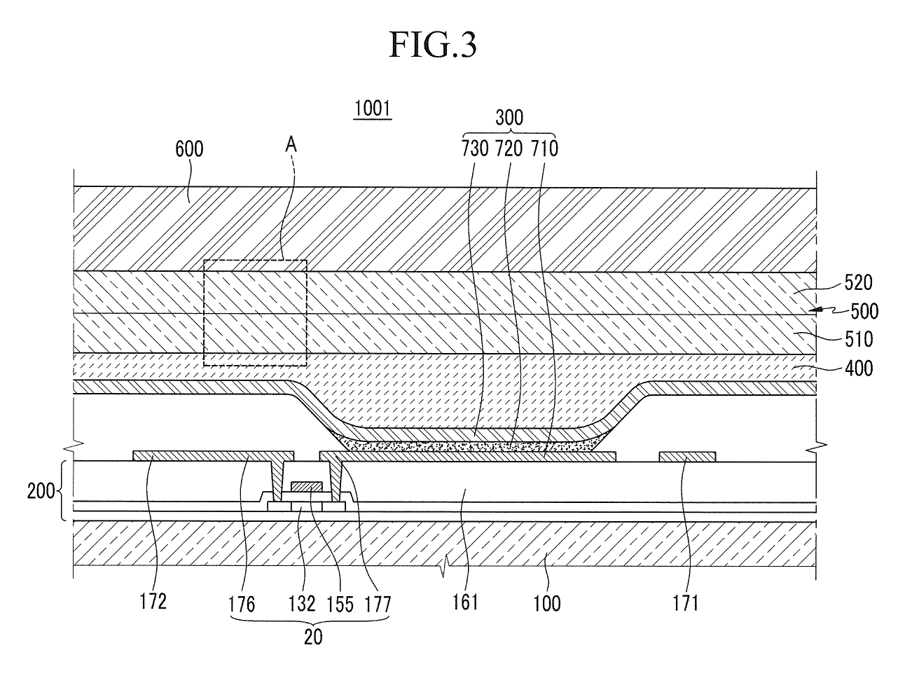

Referring to FIG. 2 and FIG. 3, a detailed configuration of the OLED display 1001 will now be described.

FIG. 2 shows a layout view for a configuration of a pixel of the OLED display 1001. FIG. 3 shows a cross-sectional view with respect to a line III-III of FIG. 2.

A detailed configuration of the wiring 200 and the OLED 300 is shown in FIG. 2 and FIG. 3. The present invention is not restricted to the configuration shown in FIG. 2 and FIG. 3. In other embodiments, the configuration of the wiring 200 and the OLED 300 may vary within the range of routine skill by a person of ordinary skill in the art.

For example, the accompanying drawings show a two-transistor one-capacitor (2Tr-1 Cap) configured active matrix (AM) type of OLED display including two thin film transistors (TFTs) and a capacitor for each pixel for the above-described OLED display 1001, but the present invention is not limited thereto. In other embodiments, the OLED display is not limited in the number of thin film transistors, capacitors, and wires. In addition, the pixel represents the minimum unit for displaying an image. The OLED display 1001 displays the image by using a plurality of pixels.

As shown in FIG. 2 and FIG. 3, the OLED display 1001 includes a switching thin film transistor 10, a driving thin film transistor 20, a capacitor 80, and an OLED 300 for each pixel. In this instance, a configuration including the switching thin film transistor 10, the driving thin film transistor 20, and the capacitor 80 will be referred to as the wiring 200. The wiring 200 further includes a gate line 151 disposed in one direction of the substrate 100, a data line 171 crossing the gate line 151 in an insulated manner, and a common power supply line 172. In this instance, a single pixel can be defined by boundaries of the gate line 151, the data line 171, and the common power supply line 172, but the present invention is not limited thereto.

The OLED 300 includes a first electrode 710, an organic emission layer 720 disposed on the first electrode 710, and a second electrode 730 disposed on the organic emission layer 720. The first electrode 710, the organic emission layer 720, and the second electrode 730 configure the OLED 300. In this instance, the first electrode 710 is an anode, which is a hole injection electrode, and the second electrode 730 is a cathode, which is an electron injection electrode. However, the present invention is not restricted thereto. In other embodiments, the first electrode 710 can be a cathode and the second electrode 730 can be an anode depending on the method used for driving the OLED display.

Holes and electrons are injected into the organic emission layer 720 from the first electrode 710 and the second electrode 730. When excitons generated by combination of the holes and the electrons injected into the organic emission layer 720 enter the ground state from the excited state, the organic emission layer 720 emits light. Further, the first electrode 710 is light transmissive and the second electrode 730 is light reflective. Hence, the OLED 300 emits light in the direction of the substrate 100.

The capacitor 80 includes a pair of capacitor plates (namely, a first capacitor plate 158 and a second capacitor plate 178) with an interlayer insulating layer 161 therebetween. Here, the interlayer insulating layer 161 is a dielectric material. The capacitance of the capacitor 80 is determined by the charges stored in the capacitor 80 and a voltage between the first and second capacitor plates 158 and 178.

The switching thin film transistor 10 includes a switching semiconductor layer 131, a switching gate electrode 152, a switching source electrode 173, and a switching drain electrode 174. The driving thin film transistor 20 includes a driving semiconductor layer 132, a driving gate electrode 155, a driving source electrode 176, and a driving drain electrode 177.

The switching thin film transistor 10 functions as a switch for selecting a pixel to emit light. The switching gate electrode 152 is connected to the gate line 151. The switching source electrode 173 is connected to the data line 171. The switching drain electrode 174 is disposed apart from the switching source electrode 173 and is connected to the first capacitor plate 158.

The driving thin film transistor 20 supplies driving power for driving the organic emission layer 720 of the OLED 300 in the selected pixel. The driving gate electrode 155 is connected to the first capacitor plate 158 connected to the switching drain electrode 174. The driving source electrode 176 and the second capacitor plate 178 are connected to the common power supply line 172. The driving drain electrode 177 is located on the same layer as the first electrode 710, and is connected to the first electrode 710.

By the above-described configuration, the switching thin film transistor 10 is operated by a gate voltage applied to the gate line 151 to transmit a data voltage applied to the data line 171 to the driving thin film transistor 20. A voltage difference between the common voltage applied to the driving thin film transistor 20 from the common power supply line 172 and the data voltage transmitted by the switching thin film transistor 10 is stored in the capacitor 80, and a current corresponding to the voltage stored in the capacitor 80 flows to the OLED 300 through the driving thin film transistor 20 to allow the OLED 300 to emit light.

As shown in FIG. 3, the adhesive layer 400 is disposed on the OLED 300 between the substrate 100 and the encapsulation layer 500, and adheres and seals the encapsulation layer 500 to the substrate 100 along the edge of the substrate 100 with the OLED 300 and the wiring 200 sealed therebetween. The adhesive layer 400 may include a heat-hardening resin. When the adhesive layer 400 includes the heat-hardened resin, it is hardened by heat. The adhesive layer 400 may include a getter for blocking moisture that comes from an end side of the OLED display 1001.

The encapsulation layer 500 is disposed on the substrate 100 with the adhesive layer 400 and the OLED 300 therebetween. The encapsulation layer 500 encapsulates the OLED 300 on the substrate 100, and includes a first metal layer 510 and a second metal layer 520 directly attached to each other.

The first metal layer 510 and the second metal layer 520 may include the same kind of metal or different kinds of metals. For instance, in the OLED display 1001 of FIG. 3, the first metal layer 510 and the second metal layer 520 may include the same kind of metal. For example, the first metal layer 510 and the second metal layer 520 may include aluminum (Al). The first metal layer 510 and the second metal layer 520 are thermally treated after they are rolled, and they are directly attached to each other.

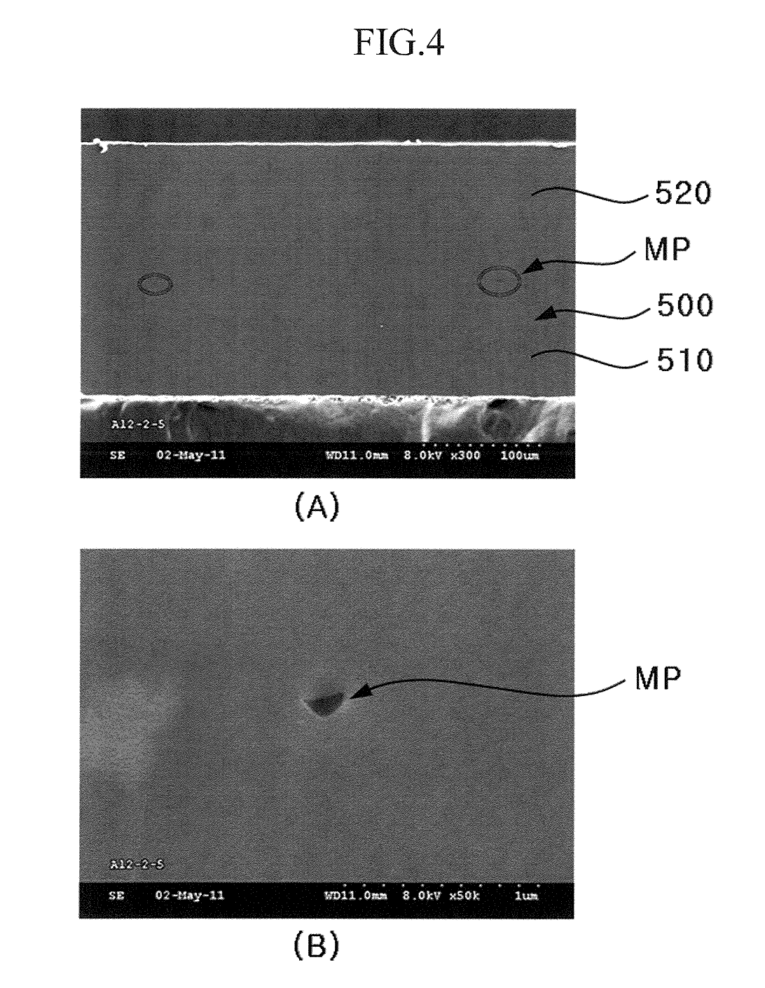

FIG. 4, which includes FIG. 4(A) and FIG. 4(B), shows enlarged photographs of part A in FIG. 3. FIG. 4(A) shows an enlarged photograph of part A of FIG. 3 at 300 times magnification with a reference scale bar representing 100 micrometers (μm), and FIG. 4(B) shows an enlarged photograph of part A with respect to micropores MP at 50,000 times magnification with a reference scale bar representing 1 μm.

As shown in FIGS. 4(A) and 4(B), micropores MP are disposed in the interface where the first metal layer 510 and the second metal layer 520 contact. The micropores MP are disposed between the first metal layer 510 and the second metal layer 520, and no adhesive layer or other types of layers are disposed therein.

The micropores MP with a size of substantially 1 μm are disposed between the first metal layer 510 and the second metal layer 520 when the OLED display 1001 of FIG. 3 is manufactured by a method for manufacturing an OLED display to be described below. Further, since the micropores MP are disposed between the first metal layer 510 and the second metal layer 520, permeation of moisture into the OLED 300 through the encapsulation layer 500 is effectively prevented.

In further detail, the inventors of the present invention have discovered that external moisture permeates into the OLED 300 through a pinhole formed in the metal layer when the encapsulation layer for sealing the OLED 300 is formed to be a single metal layer. In order to solve this problem, an adhesive was applied to a plurality of metal layers and the OLED 300 was sealed by using the encapsulation layer including a plurality of metal layers that are adhered to each other by the adhesive. However, they found that the external moisture moves to the adhesive through a pinhole formed in the metal layer located in the highest (uppermost) layer from among the plurality of metal layers. The moisture then moves through the adhesive to a pinhole formed in the metal layer located in the lowest layer from among the plurality of metal layers. Finally, the moisture permeates into the OLED 300 through the plurality of metal layers and the adhesive.

That is, regarding the encapsulation layer 500 of the OLED display 1001 of FIG. 3, the first metal layer 510 and the second metal layer 520 are not merely attached to each other. Rather, the first metal layer 510 and the second metal layer 520 are directly attached to each other so that no material that can function as a channel for the moisture between the first metal layer 510 and the second metal layer 520 exists. Accordingly, external moisture is effectively prevented from permeating into the OLED 300 through a pinhole even when an undesired pinhole is formed on both of the first metal layer 510 and the second metal layer 520.

The encapsulation layer 500 of the OLED display 1001 of FIG. 3 includes two metal layers (namely, the first metal layer 510 and the second metal layer 520). In other embodiments, the encapsulation layer of the OLED display may have at least three metal layers directly attached to each other.

In addition, the first metal layer 510 and the second metal layer 520 included in the encapsulation layer 500 of the OLED display 1001 of FIG. 3 includes aluminum. In other embodiments, the metal layer included in the encapsulation layer of the OLED display may include various kinds of metallic materials such as copper (Cu), stainless steel, Invar, platinum (Pt), gold (Au), or silver (Ag).

Referring to FIG. 3, a resin layer 600 is disposed on the encapsulation layer 500. The resin layer 600 is a reinforcing member for reinforcing strength of the encapsulation layer 500 directly attached to the second metal layer 520 located in the highest layer of the plurality of metal layers included in the encapsulation layer 500. The resin layer can include engineering plastics including at least one of glass fiber reinforced plastic (FRP), polyethylene terephthalate (PET), and polymethyl methacrylate (PMMA).

The OLED display 1001 of FIGS. 1-3 may be manufactured by a method for manufacturing an OLED display to now be described.

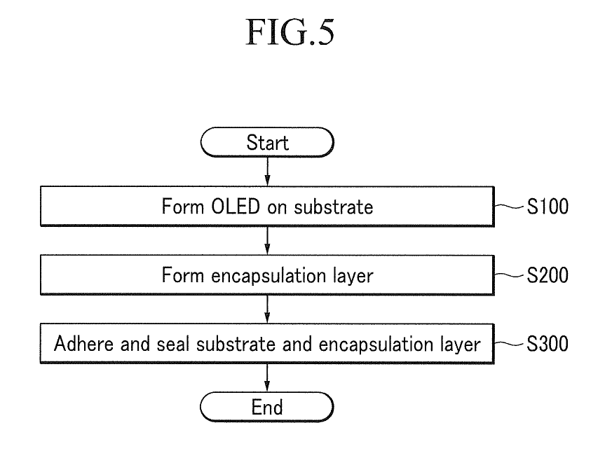

Referring to FIG. 5 to FIG. 7, a method for manufacturing an OLED display according to a second exemplary embodiment of the present invention will now be described.

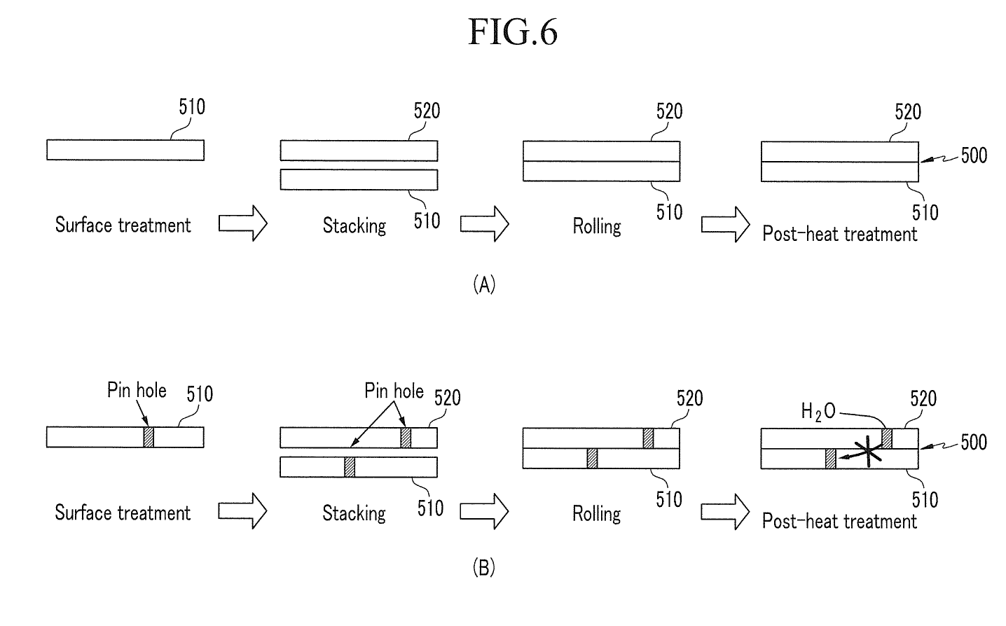

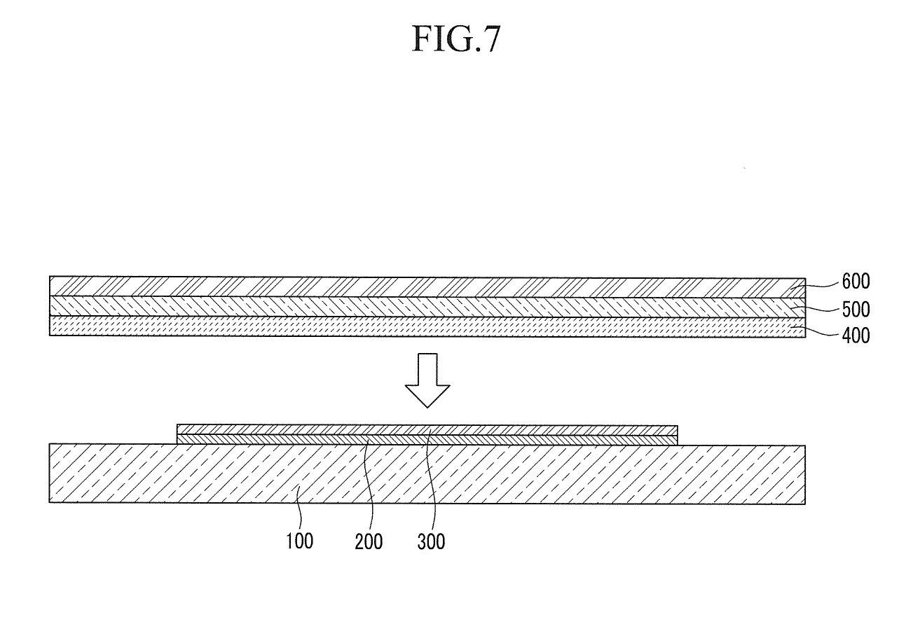

FIG. 5 shows a flowchart of the method for manufacturing the OLED display. FIG. 6 and FIG. 7 show the method of FIG. 5.

As shown in FIG. 5 and FIG. 7, an OLED 300 is formed on the substrate 100 (S100). In further detail, the wiring 200 is formed on the substrate 100 by using a microelectromechanical systems (MEMS) technology such as photolithography. The OLED 300 is formed on the wiring 200 by using a stacking process using a mask.

As shown in FIG. 5 and FIG. 6, an encapsulation layer 500 is then formed (S200). In further detail, as shown in FIG. 6(A), protrusions and depressions are formed on the surface of a first metal layer 510 by processing the surface of the first metal layer 510. The surface treatment of the first metal layer 510 can be performed, for example, by using an etching process, a brushing process, a papering process, a blasting process, or an alkaline process. Next, a second metal layer 520 is stacked on the surface of the first metal layer 510. The protrusions and depressions can also be formed on the surface of the second metal layer 520 contacting the surface of the first metal layer 510.

Then, the first metal layer 510 and the second metal layer 520 stacked with each other are rolled. The rolling process is performed by inserting the stacked first metal layer 510 and second metal layer 520 between rollers that are rotated while facing each other. Then, the rolled first metal layer 510 and second metal layer 520 are thermally treated. The mobility of molecules configuring the first metal layer 510 and the second metal layer 520 is increased by the heat treatment so that a gap in the interface between the first metal layer 510 and the second metal layer 520 that is created by the protrusions and depressions is filled by the molecules configuring the first metal layer 510 and the second metal layer 520. In this instance, as the gap located at the interface between the first metal layer 510 and the second metal layer 520 is filled, the micropores are formed in the interface between the first metal layer 510 and the second metal layer 520. Thus, the encapsulation layer 500 by which the first metal layer 510 and the second metal layer 520 are directly attached to each other is formed.

The encapsulation layer 500 is formed when the first metal layer 510 and the second metal layer 520 are directly attached to each other through surface treatment, rolling, and post-heat treatment. Hence, as shown in FIG. 6(B), when a pinhole is formed in the first metal layer 510 and a pinhole is formed in the second metal layer 520, penetration of the encapsulation layer 500 by the external moisture (e.g., H₂O) through the respective pinholes of the first metal layer 510 and the second metal layer 520 is effectively prevented.

In addition, a resin layer 600 for reinforcing strength is directly attached to the second metal layer 520 located at the highest layer from among the plurality of metal layers included in the encapsulation layer 500.

As shown in FIG. 5 and FIG. 7, the substrate 100 and the encapsulation layer 500 are adhered and sealed (S300). In further detail, an adhesive layer 400 is formed on the encapsulation layer 500 to which the resin layer 600 is attached. The substrate 100 and the encapsulation layer 500 are adhered and sealed with the OLED 300 therebetween by using the adhesive layer 400.

The OLED display 1001 of FIGS. 1-4 is manufactured by the method of FIGS. 5-7. Accordingly, regarding the OLED display 1001 of FIGS. 1-4, sealing performance of the OLED 300 is improved since penetration of the encapsulation layer 500 by external moisture (e.g., H₂O) through the pinholes of the first metal layer 510 and the second metal layer 520 is effectively prevented That is, even when a pinhole is formed in each of the first metal layer 510 and the second metal layer 520, the encapsulation layer 500 is formed when the first metal layer 510 and the second metal layer 520 are directly attached to each other by surface treatment, rolling, and post-heat treatment. This process results in the micropores that are located in the interface between where the first metal layer 510 and the second metal layer 520 of the encapsulation layer 500 contact each other. This functions as a factor for improving the overall life span of the OLED display 1001.

Further, electrical and mechanical reliability of the OLED display 1001 is generally improved since the encapsulation layer 500 effectively prevents the moisture from permeating into the OLED 300. In addition, the resin layer 600 reinforces mechanical strength of the encapsulation layer 500.

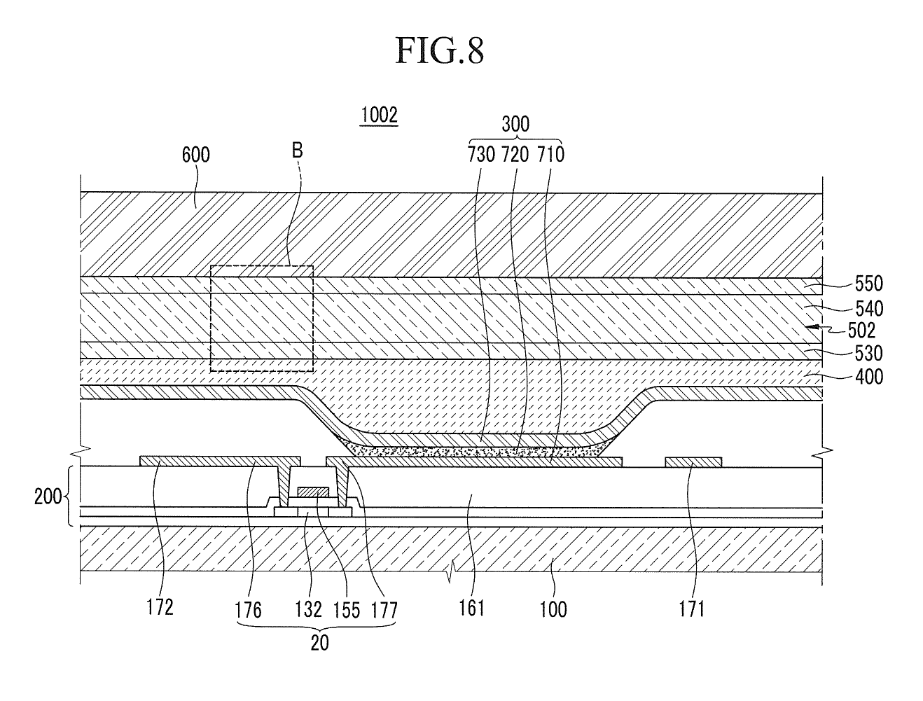

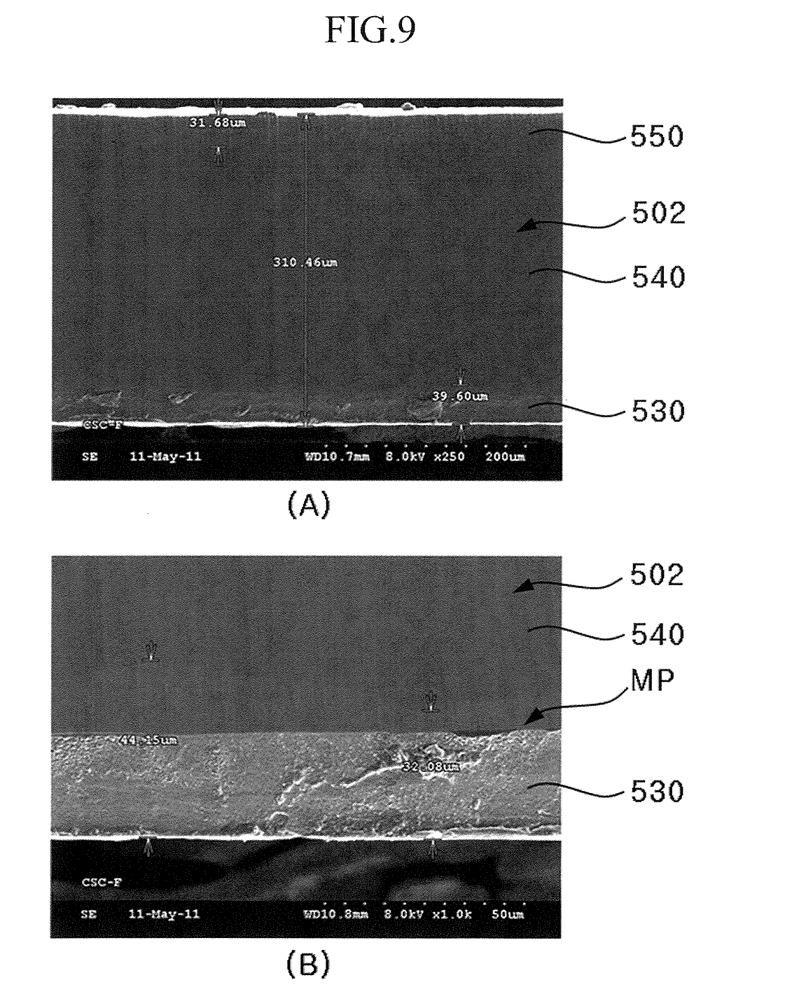

Referring to FIG. 8 and FIG. 9, an OLED display 1002 according to a third exemplary embodiment of the present invention will now be described.

Parts differing from the embodiments of FIGS. 1-7 will be described while omitted parts follow those of the earlier described embodiments. That is, the embodiment of FIGS. 8-9 will use the same reference numerals as the earlier embodiments for the same constituent elements, for better comprehension and ease of description.

FIG. 8 shows a cross-sectional view of the OLED display 1002.

As shown in FIG. 8, the encapsulation layer 502 of the OLED display 1002 represents an encapsulating member for encapsulating the OLED 300 on the substrate 100. The encapsulation layer 502 includes a third metal layer 530, a fourth metal layer 540, and a fifth metal layer 550 directly attached to each other.

The third metal layer 530, the fourth metal layer 540, and the fifth metal layer 550 can include the same kind of metal or different kinds of metal. In the OLED display 1002, the third metal layer 530 and the fifth metal layer 550 may include copper (Cu), and the fourth metal layer 540 may include stainless steel (SUS). The third metal layer 530, the fourth metal layer 540, and the fifth metal layer 550 are directly attached to each other since they are rolled and then thermally treated.

FIG. 9 shows an enlarged photograph of part B of FIG. 8. FIG. 9(A) shows an enlarged photograph of part B of FIG. 8 at 250 times magnification with a reference scale bar representing 200 μm, and FIG. 9(B) shows an enlarged photograph of part B with respect to micropores MP at 1000 times magnification with a reference scale bar representing 50 μm.

As shown in FIGS. 9(A) and 9(B), the micropores MP are located in the interfaces where the third metal layer 530, the fourth metal layer 540, and the fifth metal layer 550 contact each other. The micropores MP are located between the third metal layer 530 and the fourth metal layer 540, and between the fourth metal layer 540 and the fifth metal layer 550, and no adhesive layer or other layers are located therebetween.

The encapsulation layer 502 is formed by attaching the third metal layer 530, the fourth metal layer 540, and the fifth metal layer 550 directly through surface treatment, rolling, and post-heat treatment in a similar manner to the method of FIGS. 5-7. This results in micropores MP with the size of 50 μm being located in the interface between the third metal layer 530 and the fourth metal layer 540 and in the interface between the fourth metal layer 540 and the fifth metal layer 550. Accordingly, the micropores MP are located in the respective interfaces of the third metal layer 530, the fourth metal layer 540, and the fifth metal layer 550, thereby effectively preventing permeation of moisture into the OLED 300 through the encapsulation layer 502.

Therefore, the OLED display 1002 of FIGS. 8-9 improves the sealing performance on the OLED 300 since penetration of the encapsulation layer 502 by the external moisture (e.g., H₂O) through the pinholes of the third metal layer 530, the fourth metal layer 540, and the fifth metal layer 550 is effectively prevented. That is, even when the respective pinholes are formed in the third metal layer 530, the fourth metal layer 540, and the fifth metal layer 550, the encapsulation layer 502 is formed when the third metal layer 530, the fourth metal layer 540, and the fifth metal layer 550 are directly attached to each other by surface treatment, rolling, and post-heat treatment. This results in the micropores MP that are located in the interface between where the third metal layer 530 and the fourth metal layer 540, and between where the fourth metal layer 540 and the fifth metal layer 550 contact each other. This works as a factor for improving the overall life span of the OLED display 1002.

While this disclosure has been described in connection with what is presently considered to be practical exemplary embodiments, it is to be understood that the present invention is not limited to the disclosed embodiments, but, on the contrary, is intended to cover various modifications and equivalent arrangements included within the spirit and scope of the appended claims, and equivalents thereof.

What is claimed is:

1. An organic light emitting diode (OLED) display comprising:
a substrate;
an OLED on the substrate; and
an encapsulation layer on the substrate with the OLED therebetween, and comprising a plurality of metal layers, two of the plurality of metal layers being directly attached to each other.

2. The OLED display of claim 1, wherein micropores are provided at an interface where the two of the plurality of metal layers contact.

3. The OLED display of claim 2, wherein all of the plurality of metal layers comprise a same metal.

4. The OLED display of claim 2, wherein different ones of the plurality of metal layers comprise different metals.

5. The OLED display of claim 1, wherein each of the plurality of metal layers comprises at least one of aluminum (Al), copper (Cu), or stainless steel.

6. The OLED display of claim 1, further comprising a resin layer on the plurality of metal layers, the resin layer being configured to reinforce strength of the plurality of metal layers.

7. The OLED display of claim 6, wherein the resin layer is attached to an uppermost layer of the plurality of metal layers.

8. The OLED display of claim 7, wherein the resin layer comprises at least one of glass fiber reinforced plastic (FRP), polyethylene terephthalate (PET), or polymethyl methacrylate (PMMA).

9. The OLED display of claim 1, further comprising an adhesive layer between the substrate and the encapsulation layer and on the OLED, and configured to adhere and seal the encapsulation layer to the substrate.

10. A method for manufacturing an organic light emitting diode (OLED) display, comprising:
forming an OLED on a substrate;
forming an encapsulation layer by directly attaching two of a plurality of metal layers to each other; and
adhering and sealing the encapsulation layer to the substrate with the OLED therebetween.

11. The method of claim 10, wherein
the two of the plurality of metal layers respectively comprise a first metal layer and a second metal layer, and
the directly attaching of the two of the plurality of metal layers comprises:
forming protrusions and depressions on a surface of the first metal layer;
stacking the second metal layer on the surface of the first metal layer;
rolling the first metal layer and the second metal layer; and
heat treating the first metal layer and the second metal layer.

12. The method of claim 11, further comprising attaching a resin layer for reinforcing strength of the plurality of metal layers on an uppermost layer of the plurality of metal layers.
